(19) United States
(12) Patent Application Publication
(10) Pub. No.: US 2005/0048679 A1
(43) Pub. Date: Mar. 3, 2005

(54) Technique for adjusting a penetration depth during the implantation of ions into a semiconductor region

(76) Inventors: Christian Krueger, Liegau-Augustusbad (DE); Thomas Feudel, Radebeul (DE); Aranka Kern, Frankfurt(Oder) (DE); Thomas Beck, Ohorn (DE)

Correspondence Address: WILLIAMS, MORGAN & AMERSON, P.C., 10333 RICHMOND, SUITE 1100, HOUSTON, TX, 77042, US

(21) Appl. No.: 10/835,181

(22) Filed: Apr. 29, 2004

(30) Foreign Application Priority Data
Aug. 29, 2003 (DE) 103 39 991.7

(51) Int. Cl. H01L 21/00

(52) U.S. Cl. 438/5; 438/528

(57) ABSTRACT

By significantly suppressing or eliminating the channeling effects during implantation of a dopant species into the semiconductor region, the contribution of energy contamination may be studied and the corresponding results may be used in selecting appropriate tool settings for an actual implantation process. In this way, the vertical dopant profile may be controlled more precisely than in conventional processes. In one particular embodiment, the channeling effect is suppressed by an appropriately performed amorphization implantation process.

### BACKGROUND OF THE INVENTION

1. Field of the Invention

The present invention generally relates to the fabrication of microstructures, such as integrated circuits, and, more particularly, to ion implantation processes required for producing well-defined dopant profiles in semiconductive regions.

2. Description of the Related Art

The fabrication of complex microstructures, such as sophisticated integrated circuits, requires that a large number of individual process steps be performed to finally obtain the required functionality of the microstructure. Especially in the formation of integrated circuits, the conductivity of specific areas has to be adapted to design requirements. For instance, the conductivity of a semiconductor region may be increased in a well-defined manner by introducing specific impurities, which are also referred to as dopants, and placing some or preferably all of these impurities at lattice sites of the semiconductor crystal. In this way, so-called PN junctions may be formed that are essential for obtaining a transistor function, since transistors represent the active elements, i.e., elements providing current or voltage amplification, which are required for manufacturing electronic circuits.

In modern integrated circuits, typically millions of transistor elements, such as field effect transistors, are provided on a single die, wherein, in turn, hundreds of die are typically provided on a single substrate. As the critical dimensions of certain circuit elements, such as field effect transistors, have now reached 0.1 μm and even less, it is of great importance to correspondingly “fine-tune” the profile of doped regions in the lateral direction, with respect to a substantially planar substrate, as well as in the depth direction. That means that the dopant profile along the depth direction is characterized by the penetration depth with respect to a defined substrate surface.

Commonly, ion implantation is the preferred method for introducing dopants into specified device regions due to the ability to center the impurities around a desired depth and to relatively precisely control the number of dopant atoms implanted into substrates with repeatability and uniformity of better than ±1%. Moreover, impurities that are introduced by ion implantation have a significantly lower lateral distribution when compared to conventional dopant diffusion processes. Since ion implantation is typically a room temperature process, the lateral profiling of a doped region may in many cases conveniently be achieved by providing a correspondingly patterned photoresist mask layer. These characteristics may render ion implantation, currently and in the near future, the preferred technique to produce doped regions in a semiconductor device.

Implantation of dopants is accomplished by various ion implantation tools. Such tools are extremely complex machines that require continuous monitoring of the machine characteristics so as to achieve high efficiency and machine utilization.

With reference to FIG. 1, a schematic overview is given for a typical ion implantation tool and the operation thereof. In FIG. 1, an ion implantation tool 100 comprises an ion source 101 having an input 102 that is connected to respective precursor sources (not shown) from which an appropriate ion species may be created in the ion source 101. The ion source 101 may be configured to establish a plasma atmosphere and to pre-accelerate charged particles into a beam pipe, schematically depicted as 103. A typical voltage for the pre-acceleration of the ions may range from approximately 500 V to 50 kV. Downstream of the ion source 101, an accelerator tube 104 is arranged that is dimensioned to accelerate ions with a specified voltage, which may typically range from 0 V to approximately 200 kV for a typical medium current implanter and may range to several hundred kVs or even to 1 MV or more in high-energy implanters.

Next, a beam shaping element 105 such as a quadrupole magnet may be arranged followed by a deflector magnet 106. Downstream of the deflector magnet 106 is disposed an analyzing aperture, for instance in the form of a slit 107, the dimensions of which substantially determine an energy spread of the ion beam. Additionally, a further beam shaping element, such as a quadrupole magnet 108, may be provided downstream of the analyzing slit 107.

A substrate holder 109 is located at the vicinity of the end of the beam pipe 103, wherein typically the substrate holder 109 may be provided in the form of a plate enabling the receipt of one or more substrates 110, wherein the plate 109 is connected to a drive assembly (not shown) that allows moving of the substrate holder 109 in the transverse direction (as indicated by the arrows depicted in FIG. 1) and also allows control of the tilt angle, at least in two planes, at which the ion beam hits the substrate 110. For convenience, corresponding means for controlling and adjusting the tilt angle are not shown. Moreover, an ion beam detector 111 may be provided, for instance embodied by a plurality of Faraday cups that are connected with respective current measurement devices.

During operation of the ion implantation tool 100, an appropriate precursor gas is supplied by the inlet 102 to the ion source 101 and ions of atoms included in the precursor gases may be accelerated into the beam pipe 103 with a specified pre-acceleration or extraction voltage. Typically, a plurality of different ions having different charge states may be supplied by the ion source 101 and may thus be introduced into the acceleration tube 104. Typically, a pre-selection of the type of ions as well as of the respective charge states may be performed within the ion source 101 by a corresponding deflector magnet (not shown).

Thereafter, the ions pass the accelerator tube 104 and gain or lose speed in accordance with the applied acceleration voltage, the charge states of the respective ions and their corresponding mass. With the quadrupole magnet 105, the ion beam may be focused in one dimension and may be correspondingly defocused in the perpendicular dimension and the correspondingly shaped beam is directed to the deflector magnet 106. The current generating the magnetic field of the deflector magnet 106 is controlled so as to deflect the trajectory of a desired ion species having a desired charge state to the opening of the analyzing slit 107. Ions of differing mass and/or charge state will typically hit the analyzer 107 without passing through the slit 107. Thus, the ions in the beam passing the analyzing slit 107 have a well-defined mass and an energy distribution defined by the slit size. It should be noted that in some ion implantation tools the deflecting magnet 106 and the analyzing slit 107 are configured such that the ion beam passing through the analyzing slit 107 may be scanned in a transverse direction so as to cover the whole area of a substrate or at least a significant portion thereof, since the dimension of the beam shape, i.e., the size of the beam spot, is usually, depending on the energy of the ion beam, significantly less than the area of a substrate to be processed.

Next, the beam passing through the analyzer 107 may be further shaped by the quadrupole magnet 108 so that, in combination with the quadruple magnet 105, a desired beam shape may be obtained. The characteristics of the ion beam, i.e., the beam shape, the angle of incidence onto the substrate holder 109 and the internal parallelism, i.e., the beam divergence, and the like, may be measured prior to actually exposing the substrate 110 to the ion beam.

Although the above-described procedure for operating the implantation tool 100 allows formation of appropriate vertical and lateral dopant profiles for transistor devices having critical dimensions on the order of magnitude of approximately 0.2 μm, problems may arise for devices having significantly smaller feature sizes for the following reasons. Extremely reduced critical dimensions of transistor devices, such as the channel length of a field effect transistor, may require extremely shallow dopant profiles for the definition of drain and source regions including shallow highly doped extension regions forming a PN junction with the transistor channel region so as to provide the required transistor function. Consequently, the implantation energy may range, depending on the dopant species, from approximately 500 eV to about 10 keV, thereby requiring the accelerator tube 104 to slow down the ions provided by the ion source 101, since the ions are typically extracted with an energy of several keV so as to obtain high beam currents. During their way down the beam pipe 103, some of the ions may interact with neighboring ions and gas residues within the beam pipe 103, wherein some of the particles may be discharged partially or completely. In addition to a changed charge state, after such a collision, the involved particle may also exhibit a different energy, thereby causing an increased energy spread of the particle beam finally arriving at the substrate 110. Since the charge state has changed, the resulting particle current may not be correctly measured or may not be measured at all, depending on whether the involved particles have been discharged partially or completely, as these particles will contribute to the current measured by the Faraday cups 111 only partially or not at all, although these particles may contribute to the resulting vertical dopant profile in a non-negligible amount.

For instance, if ions of charge state 1 are considered, the above-described interactions with gas residues may create a portion of neutral particles that interact upon arrival at the substrate 110 less intensively compared to the charged particles, and that may therefore penetrate more deeply into the substrate 110, as is expected for the charged particles, while at the same time the beam detector 111 detects a smaller implantation dose as actually arrives at the substrate 110. A corresponding portion of a dopant profile created by particles of a changed charge status, which may not, or at least not correctly, be measured by beam current measurements, are referred to as “energy contamination.” Consequently, owing to the energy contamination, the actual particle dopant profile may significantly deviate from the desired dopant profile, thereby deteriorating device performance of highly scaled transistor devices.

A further effect that significantly complicates the formation of precisely controlled vertical dopant profiles in crystalline semiconductor regions is the phenomenon called channeling, which may occur when charged particles moving along substantially parallel trajectories hit the crystalline substrate region closely with respect to a crystal axis or plane of low order, such as (100) axis, (110) axis and the like. The charge distribution of the lattice atoms may then form a “channel” for the incoming ion, thereby reducing the interaction of the ion with the crystal atoms and increasing the penetration depth considerably compared to non-channeling ions, thereby creating a high variance with respect to an average penetration depth. As a consequence, the effects of energy contamination and ion channeling may significantly distort a dopant profile in the vertical direction, which may not be compatible with the requirement of shallow PN junctions of highly scaled transistor devices.

In view of the problems identified above, a need exists for an improved implantation technique that enables the control of penetration depth during the implantation of a specified dopant species.

### SUMMARY OF THE INVENTION

Generally, the present invention is directed to a technique that enables efficient identification of the contribution of energy contamination to a resulting dopant profile so that, based on the identified energy contamination, appropriate implantation tool settings may be selected so as to provide a required shallow dopant profile. As presently explained, it may be very difficult to determine the contribution of the energy contamination part owing to the fact that partially or completely discharged particles contribute to the resulting dopant profile, which may therefore not correctly be identified by current measurements. Moreover, the energy contamination is a tool-specific effect, whereas channeling is a substrate-specific effect, both of which may, however, affect the final dopant profile in a similar manner. The present invention takes advantage of the fact that the effect of channeling and the effect of energy contamination originate from quite different mechanisms. To this end, the present invention provides a technique to separately investigate the mechanism for energy contamination by using substrates having formed thereon a pre-amorphized semiconductor region or an appropriately oriented substrate, in which a shallow dopant profile is to be created, thereby substantially “filtering out” the channeling mechanism. Due to the amorphized or appropriately oriented region, any preferred crystalline directions are substantially eliminated so that the energy contamination may represent the dominant contribution to a distortion of the dopant profile compared to a profile as would be expected for an implantation process without an ion-ion or an ion-residue gas atom interaction. Based on the determination of the corresponding energy contamination created during a specified implantation process, the process may then correspondingly be controlled so as to take account of the effect of the energy contamination to obtain a desired vertical dopant profile.

According to one illustrative embodiment of the present invention, a method of forming a dopant profile in a semiconductor region is provided. The method comprises determining an amount of energy contamination caused by a specified implantation tool for at least one tool setting by implanting a specified ion species with a specified implantation energy into a substantially amorphous substrate. Then, a corrected tool setting is determined for the specified implantation energy on the basis of the determined amount of energy contamination. Additionally, the specified ion species is implanted into the semiconductor region with the specified implantation tool operated with the corrected tool setting.

According to another illustrative embodiment of the present invention, a method of adjusting a penetration depth of ions comprises providing a substantially amorphized semiconductor layer on a substrate, wherein the substantially amorphized semiconductor layer has a predefined depth. Furthermore, penetration depths within the substantially amorphized semiconductor layer are determined for a specified ion species for a specified implantation tool for a plurality of different tool settings at a predefined desired implantation energy. Then, based on the determined penetration depths, a tool setting is selected in conformity with a desired dopant distribution and the ion species is implanted with the desired implantation energy into a second substrate having provided thereon the substantially amorphized semiconductor layer.

According to a further illustrative embodiment of the present invention, a method of adjusting an implantation tool used for creating a desired dopant profile in a semiconductor region comprises implanting a specified ion species into a pre-amorphized portion of the semiconductor layer at a desired implantation energy. A dopant profile of the ion species is determined in the pre-amorphized region and a contribution of the dopant profile is estimated, which is substantially created by non-charged particles. Finally, a tool setting is selected for the implantation tool for the desired implantation energy for the specified ion species on the basis of the estimated contribution.

According to still a further illustrative embodiment of the present invention, an implantation tool comprises an ion generation source configured to create ions of at least one specified species with a controllable average extraction energy. A controllable acceleration section is provided and is configured to apply a specified energy to the specified species. The implantation tool further comprises a mass and energy discriminator configured to select a mass and an implantation energy of particles entering the mass and energy discriminator. A vacuum source is connected to a beam pipe and a control unit is operatively connected to at least the ion generation source and the controllable acceleration section, wherein the control unit is configured to control a non-charged particle flow created during the implantation of the specified species on the basis of at least one depth profile of the specified species implanted into a specified semiconductor region.

### BRIEF DESCRIPTION OF THE DRAWINGS

The invention may be understood by reference to the following description taken in conjunction with the accompanying drawings, in which like reference numerals identify like elements, and in which:

FIG. 1 schematically illustrates an ion implantation tool including an ion beam detection system as is presently employed in monitoring and adjusting an ion beam;

FIGS. 2a and 2b represent graphs illustrating energy contamination contributions determined according to illustrative embodiments of the present invention; and

FIG. 3 schematically depicts an implantation tool for controlling the amount of energy contamination in an automated manner.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

As previously explained, the present invention is based on the concept of eliminating or significantly reducing the influence of the effect of ion channeling so that implantation tool parameters may be selected so as to also minimize the influence of energy contamination on the finally-obtained dopant profile. Reducing the channeling effect may be accomplished by substantially destroying low-order crystalline symmetries by substantially avoiding the exposure of low-order crystalline symmetries to an impinging ion beam or by providing a substantially amorphized semiconductor layer or any other appropriate substantially amorphous substrate. In this way, the influence of channeling is “filtered” out, at least to a significant degree, so that the effect of energy contamination may be taken into account by correspondingly adjusting at least one tool parameter that has a significant influence on the number of ions that may undergo a change of charge status prior to interacting with the substrate. Moreover, the “efficiency” or effect of various “filter” mechanisms may be examined, such as a pre-amorphization implantation, to select a suitable filtering process during the implantation process of actual product substrates.

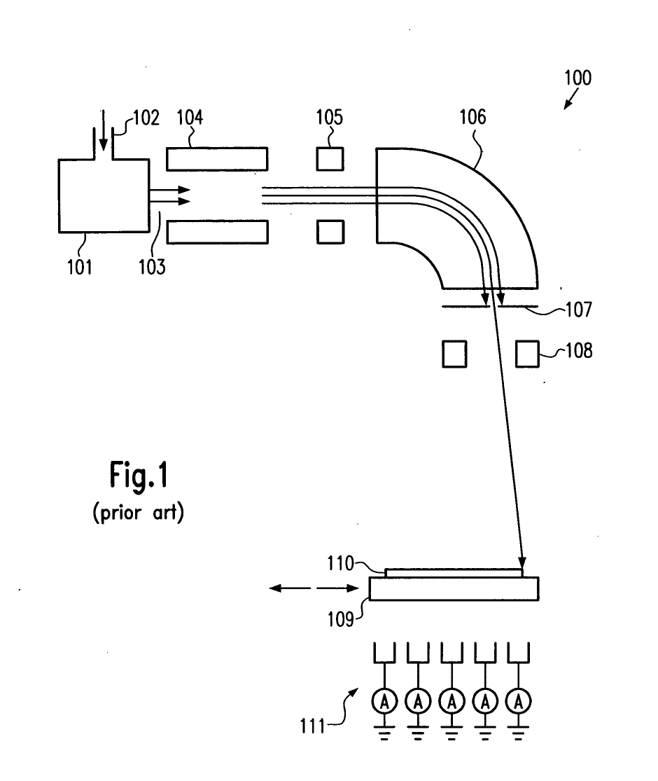

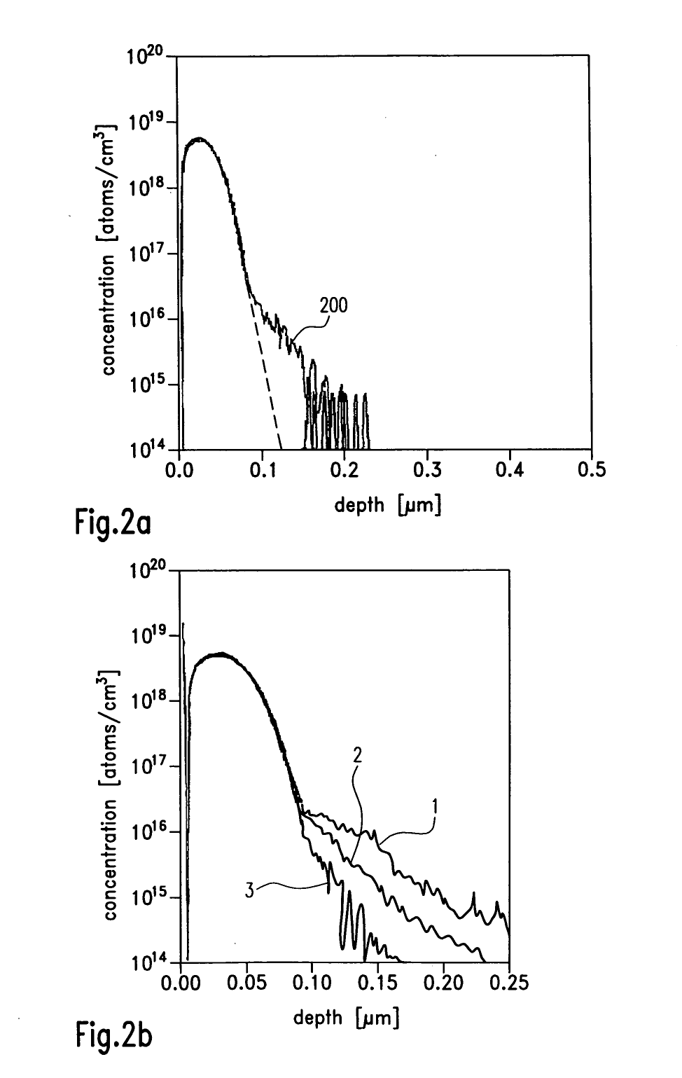

With reference to FIGS. 1, 2a and 2b, the basic concept of the present invention is described in more detail by referring to further illustrative embodiments of the present invention. It is now assumed that the implantation tool 100 is operated as described with reference to FIG. 1. For instance, the substrate 110 is to receive a shallow dopant profile, for instance a boron profile, with an implantation energy in the range of approximately 0.5-10 keV, for example 9 keV. In one example, the extraction energy for creating the boron ions in the ion generating source 101 and for supplying the released ions into the beam pipe 103 may be selected to be 30 kV. Prior to the actual boron deposition, the implantation tool 100, or a second implantation tool (not shown), may be operated so as to provide a substantially amorphized semiconductor region on the substrate 110. Typically, this pre-amorphization implantation step may be performed by using a heavy ion species that creates intensive damage on the crystalline structure, even if provided at moderately low doses. In some illustrative embodiments, a dose of approximately 5×10¹³ to 4×10¹⁴ ions/cm² may be used with ion species such as germanium, xenon, argon, silicon, and the like. It should be noted, however, that any other ion species may be used for the pre-amorphization implantation as long as the desired requirements in view of implantation time are met. Moreover, for establishing a relationship between at least one tool parameter and the effect of energy contamination, the ion species used for the pre-amorphization implantation has to be distinguishable in subsequent measurement procedures from the actual dopant species, such as the boron mentioned above.

Since the pre-amorphization implantation is performed to substantially reduce or even completely eliminate any channeling effects in the substrate 110 during the actual implantation for depositing the required dopants, such as boron and like, the implantation energy for the pre-amorphization implantation is selected so as to produce substantial crystalline damage up to a depth that allows substantial confinement of dopants of the subsequent actual implantation process within the damaged, i.e., substantially amorphized, layer. For instance, the expected penetration depths of the dopants under consideration, for example the boron, may be estimated on the basis of well-established simulation algorithms while assuming a substantially amorphous substrate 110. The corresponding projected penetration range Rₚ may thus represent the corresponding penetration depth of the dopant. The straggling or variance ΔRₚ of the projected penetration range may also be obtained from the simulation calculations, and the corresponding implantation energy of the pre-amorphization implantation may be selected so as to at least significantly damage the substrate 110 up to a depth defined by Rₚ+2×ΔRₚ. However, the implantation energy during the pre-amorphization implantation step may be selected to be higher than proposed by the above simulation calculations so as to provide a security margin to reliably confine the subsequently implanted dopants within the substantially pre-amorphized region of the substrate 110. For example, for the above-specified boron implantation, a pre-amorphization implantation may be performed with Xe⁺ as the pre-amorphization species at an implantation energy of approximately 130 keV at an implantation dose of approximately 2×10¹⁴ ions/cm². With these parameters and with a silicon substrate, a depth of a substantially amorphized layer of approximately 130 nm is obtained.

It should be noted that other techniques may be considered for providing a substantially amorphized semiconductor region, whereas the provision of the substantially amorphized semiconductor region by a corresponding pre-amorphization implantation step is highly compatible with standard manufacturing process flows for fabricating, for instance, sophisticated CMOS devices. Since providing the substantially amorphized semiconductor region by an implantation step may readily be implemented into a standard process flow, it may be advantageous to also prepare any test substrates by using the pre-amorphization implantation so as to take account of any possible subtle effects on the subsequent measurements regarding the energy contamination that may be caused by the pre-amorphization implantation. That is, the degree of destruction of the crystalline structure may slightly depend on the conditions of the pre-amorphization step. Thus, by using substantially the same pre-amorphization conditions for obtaining appropriate tool settings for the actual implantation process, which will also be performed by using the same pre-amorphization implantation step, the accuracy of the process control may be improved.

In other embodiments, the substantially amorphized region of the substrate 110 may be provided by forming a substantially amorphous semiconductor layer on the substrate 110, wherein during the actual processing of product substrates the provision of the substantially amorphized semiconductor region may be accomplished by the above-described pre-amorphization implantation or, if compatible with process requirements, by providing a respective substantially amorphous semiconductor layer.

In other embodiments, the effect of channeling during the implantation of a required ion species, such as the boron, may significantly be reduced by correspondingly tilting the substrate 110 with respect to the incoming ion beam, thereby substantially avoiding an interaction of the ion beam with low order crystalline symmetries, such as the (100) direction. In this way, only crystalline directions of higher order are exposed to the incoming ion beam in which the correspondingly created channels are significantly less pronounced, thereby remarkably reducing the channeling effect. A corresponding tilt angle may be appropriate for obtaining representative test dopant profiles for the ion species under consideration, or in other cases may be appropriate for forming a shallow vertical dopant profile, if no specific lateral patterning of the dopant profile is required. For instance, a threshold voltage implantation may be carried out in which substantially no lateral patterning may be required so that the substrate may be tilted without adversely affecting the finally obtained dopant profile. Due to the compensated energy contamination, the vertical dopant distribution is controlled more precisely compared to conventional implantation cycles in which channeling effects and energy contaminations are not accounted for.

Although the preceding illustrative embodiments use the same semiconductor material for determining the amount of energy contamination for one or more tool settings and for one or more desired implantation energies and ion species, in other embodiments, corresponding measurement data may be obtained from any amorphous substrate, since the energy contamination is substantially determined by tool-specific characteristics rather than by substrate-specific characteristics. Thus, the relationship between relevant tool parameters and the amount of energy contamination caused by various tool status of a specified implantation energy may be obtained by any amorphous material, such as silicon dioxide, silicon nitride, amorphous silicon, and the like. As previously discussed, a corresponding channeling filtering process for the actual implantation has to then be selected and its efficiency has to be determined.

Again referring to FIG. 1, after the substrate 110 is prepared to have a substantially amorphized region with an appropriate depth to receive the actual dopant species, the tool setting is adjusted so as to obtain the desired final implantation energy of the boron, such as 9 keV as in the above-mentioned example. Hence, the voltage of the acceleration tube 104 is selected so as to decelerate the ions provided by the ion generating source 101 with an energy of approximately 30 kV. It should be appreciated that the further beam optics elements 105, 108 as well as the deflecting magnet 106 are correspondingly adjusted so as to provide the desired implantation species with the required implantation energy. The frequency with which ions interact with gas residues within the beam pipe 103 may depend on the vacuum prevailing within the beam pipe 103, the energy with which the ions are supplied by the ion generating source 101, the final implantation energy, the geometric configuration of the implantation tool 100, and the like. As a consequence, the finally obtained vertical dopant profile may vary for different tool settings and for different implantation tools, although the penetration depth determining parameter, that is, the implantation energy, is the same. Since, according to the present invention, the influence of channeling may be efficiently suppressed or even eliminated, the accuracy of controlling a vertical dopant profile may be significantly enhanced in that the influence of energy contamination is additionally investigated so as to obtain a relationship between at least one tool parameter and the corresponding energy contamination. The corresponding results may then be used to effectively control the operation of an implantation tool so as to obtain a dopant profile having a desired accuracy in the vertical dimension.

FIG. 2a shows an illustrative measurement result of a vertical dopant profile of the substrate 110 after a boron implantation with an energy of 9 keV, wherein the effect of channeling of boron ions in the substrate 110 is suppressed or eliminated by one of the previously described methods. In the example shown in FIG. 2a, a pre-amorphization implantation has been carried out with Xe at an implantation energy of 130 keV at a dose of 2×10¹⁴ ions/cm². Subsequently, boron has been implanted with a dose of 3×10¹³ ions/cm² at an implantation energy of 9 keV. In FIG. 2a, the vertical axis denotes the corresponding boron concentration in atoms/cm³, whereas the horizontal axis indicates the corresponding penetration depth in the substrate 110, that is, the substantially amorphized portion of the substrate 110 obtained by the preceding pre-amorphization implantation process.

As is evident from FIG. 2a, the peak concentration of boron is located at approximately 0.04 μm, wherein the concentration does not drop to a negligible concentration of approximately 10¹⁵ within a depth of approximately 0.1 μm as would be expected for a substantially monoenergetic boron beam without any non-charged particles, indicated by the dashed line. Rather, a significant boron concentration is still observable at a depth between approximately 0.1-0.15 μm, as is indicated by 200. This part of the boron distribution is considered to be caused by energy contamination, as previously explained. Consequently, by providing a substantially amorphous substrate, for example in the form of an amorphized semiconductor region obtained by a pre-amorphization implantation as described above, the channeling effect may be substantially filtered out so as to allow observation of the profile distortion caused by energy contamination.

As previously explained, the contribution of energy contamination to the finally-obtained dopant profile may significantly be influenced by the currently-used tool setting and may also be affected by the current tool status. For instance, a slight deterioration of the vacuum established in the beam pipe 103 may increase the number of collisions that charged particles undergo, thereby also increasing the number of non-charged particles, which may then in turn increasingly contribute to the energy contamination. Moreover, the extraction voltage, i.e., the voltage with which the ions are supplied by the ion generating source 101, and thus the corresponding acceleration voltage required for adjusting the desired final energy, may also have a significant influence on the degree of energy contamination. It is believed that ions of higher energy change their charge status more frequently as compared to ions of lower energy so that, for instance during a deceleration period to obtain the desired final low energy, a larger number of non-charged particles are produced, thereby also increasing the energy contamination. Other factors that may influence the energy contamination during an implantation process may be the tool-specific arrangements of the individual components, such as the deflector magnet 106, the analyzing slit 107, the beam shaping elements 105, 108, and the like.

FIG. 2b schematically shows the variation of a boron concentration profile when using three different extraction voltages for the same final implantation energy when using a Varian EHP500™ implanter, wherein the parameters for the pre-amorphization implantation and the parameters for the boron implantation are the same as used for creating the curve shown in FIG. 2a.

A curve 1 in FIG. 2b represents the boron implantation with an extraction voltage of 30 kV, i.e., requiring a deceleration voltage of 21 kV to obtain the final energy of 9 keV. A curve 2 is obtained by an extraction voltage of 25 kV, ie., a deceleration voltage of 16 kV is required for the final energy of 9 keV. Similarly, a curve 3 represents the dopant concentration obtained by an extraction voltage of 20 kV, i.e., a deceleration voltage of 11 kV for the final energy of 9 keV. During the three implantation cycles, the vacuum in the beam pipe 103 has been kept substantially constant so that the curves 1, 2 and 3 illustrate the change of the dopant profile by varying the extraction voltage, and thus the required deceleration voltage, while maintaining other tool parameters substantially constant. FIG. 2b indicates that the given implanter may be tuned by correspondingly selecting the extraction voltage and thus the corresponding deceleration voltage for a desired final energy. For instance, if a minimum vertical spread of the dopant concentration is desired, the parameter setting of curve 3 may be selected so as to obtain the desired profile. It should be emphasized that the curves 1, 2 and 3 may vary slightly depending on the implantation parameters of the preceding pre-amorphization implantation or, as previously explained, on the characteristics of the semiconductor region into which the boron is implanted. That is, if the channeling effect is suppressed or eliminated by providing the substrate 110 having formed thereon a semiconductor layer that is, per se, amorphous, the shape of the curves 1, 2 and 3 may also vary slightly.

In other embodiments, when the substrate 110 is correspondingly tilted with an angle in the range of approximately 5-10 degrees with respect to a crystalline orientation and the incoming ion beam, the channeling effect may not be compensated as effectively as in the case of a corresponding pre-amorphization implantation or by providing an amorphous semiconductor layer. Therefore, it may be advantageous to create the curves 1, 2, 3, which may be used as calibration curves, for a given implanter and for a desired implantation energy range in combination with an appropriate method for suppressing or substantially eliminating the channeling effect, as is also intended to be used during the manufacturing of actual product substrates. That is, if the formation of shallow drain and source implantations is considered, in one particular embodiment, the channeling effect is suppressed by a corresponding filter implantation with an appropriate implantation material that produces high crystalline damage at low implantation doses so as to reduce process time. Moreover, in one particular embodiment, the implanted ions may be inert ions with respect to the semiconductor region to which the ions are implanted. For instance, if silicon-based semiconductors are considered, germanium, silicon, xenon, argon, and the like may be considered as appropriate candidates for pre-amorphization of the corresponding silicon region substantially without affecting the electronic characteristics of the basic semiconductor material. Any heavy noble gas atoms may be considered as viable candidates for the pre-amorphization implantation for any type of semiconducting material.

Based on the appropriately selected pre-amorphization implantation, corresponding calibration curves may then be established for a desired energy range for the dopant under consideration, for instance boron. It should be noted that the finally selected tool setting for an implantation process may not necessarily be based on the final implantation energy, but may be based on the required actual dopant profile. For instance, if a dopant profile is required having a graded progression in the vertical direction other than is expected for an ideal implantation process, the energy contamination may be taken advantage of and a corresponding tool setting may be selected, such as curve 1 in FIG. 2b, so as to obtain the required profile. If, at the same time, a certain penetration depth shall not be exceeded, the implantation energy may be selected correspondingly lower than 9 keV so as to obtain a peak concentration at a desired shallow depth while nevertheless forming a desired moderately high concentration at a large depth.

In other embodiments, it may be desirable to substantially confine the vertical dopant concentration within a shallow semiconductor region so that corresponding calibration curves may be established for a plurality of pre-amorphization implantations, different implantation tools, tool settings, and the like so that an optimum tool setting may be selected from these calibration curves, such as the curve 3 in FIG. 2b.

After selecting an appropriate tool setting and a corresponding implantation sequence that is compatible with the remaining manufacturing process flow for actual product substrates, the implantation tool such as the tool 100 is correspondingly operated, wherein the resulting dopant profile in the product substrates is more precisely controllable compared to conventional implantation processes which may not allow effective compensation for channeling effects and energy contamination effects.

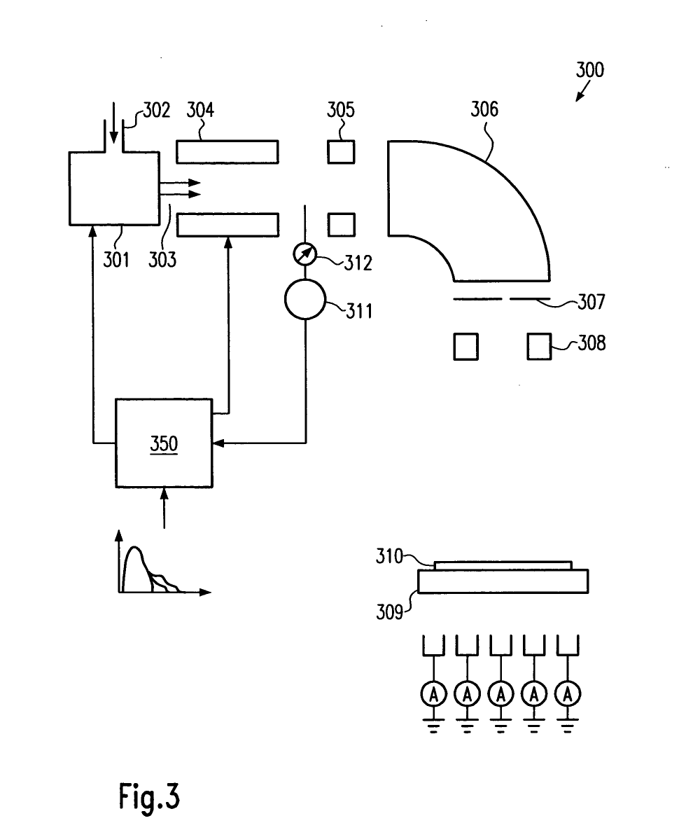

FIG. 3 schematically shows an implantation tool 300, representing an arbitrary implantation tool such as the tool 100, however additionally comprising a control unit 350 that is configured to perform one or more of the above-described steps in an automated manner. Components that are identical to the components as shown in FIG. 1 are denoted by the same reference numerals, except for a “3” instead of a “1” as the first digit, and a corresponding description of these components is therefore omitted here.

The control unit 350 is operatively connected to the ion generating source 301 and to the accelerator tube 304. Moreover, a vacuum source 311 including a pressure measurement device 312 may also be connected to the control unit 350. Furthermore, the control unit 350 is configured to receive calibration data, for instance in the form of one or more calibration curves, regarding the implantation tool 300 for at least one specified implantation sequence as is required for the manufacturing of product substrates 310. It should be appreciated that the control unit 350 is configured to store at least one calibration curve in any appropriate manner so that the stored data representing the calibration curve may be available for further processing steps within the control unit 350 so as to operate the implantation tool 300 on the basis of the stored data and a required dopant profile to be created in a semiconductor region of the substrate 310.

In one embodiment, the control unit 350 may have stored a plurality of calibration curves or data corresponding thereto, so that a readjustment of the tool setting may be performed by the control unit 350 upon a change of a current tool status or upon request of a specified vertical dopant profile. For instance, the control unit 350 may monitor the vacuum in the beam pipe 303 and may select appropriate values for the extraction energy of the ion generating source 301 and the deceleration voltage of the accelerator tube 304 so as to minimize variations of the finally-obtained dopant profile. For instance, the implantation tool 300 may be operated with an initial vacuum pressure that may, for instance, be slightly higher than during a typical operation period of the tool 300, as may be caused by a preceding idle or maintenance period. Upon processing of a plurality of substrates 310, the vacuum pressure may decrease and the control unit 350 may correspondingly increase the extraction voltage and, as well, the deceleration voltage in a subsequent implantation cycle so as to substantially maintain the resulting dopant profile in the substrates 310. It should be appreciated that the above-described control operation is of illustrative nature only and any other control scheme may be performed on the basis of the calibration data that may be obtained as previously explained with reference to FIGS. 2a and 2b. Moreover, the control unit 350 may be implemented in a facility management system that controls the operation of a plurality of manufacturing tools and metrology tools, or may be provided as a stand-alone device, or the control unit 350 may be implemented into the implantation tool 300.

As a result, the present invention allows the investigation of energy contamination during the implantation process for doping a semiconductor region on a substrate. During an actual implantation process, the effect of channeling may be significantly suppressed or eliminated in that a portion of the semiconductor region is provided in a substantially amorphized form. Preferably, the substantial amorphization of a portion of the semiconductor region is accomplished by an implantation process with an appropriate ion species so as to create crystal damage up to a depth that is sufficient to substantially completely confine the dopants of the subsequent actual doping process. Since the channeling effect is significantly suppressed, the influence of energy contamination may be compensated for or may be advantageously exploited for an implantation tool under consideration by selecting appropriate tool settings on the basis of correspondingly obtained calibration data concerning the energy contamination. These tool settings may then be used during an actual manufacturing process so as to more precisely control the vertical dopant profile within a semiconductor region of product substrates. Thus, by using the implantation tool operated by the tool setting established in accordance with the present invention, production yield may be increased.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

1. A method of forming a dopant profile in a semiconductor region, the method comprising:
determining an amount of energy contamination caused by a specified implantation tool for at least one tool setting by implanting a specified ion species with a specified implantation energy into a substantially amorphous substrate;
determining a corrected tool setting for said specified implantation energy on the basis of said determined amount of energy contamination; and
implanting said specified ion species into said semiconductor region with said specified implantation tool operated with said corrected tool setting.

2. The method of claim 1, further comprising substantially amorphizing at least a portion of said semiconductor region prior to implanting said specified ion species when said semiconductor region is initially a crystalline semiconductor region.

3. The method of claim 1 or 2, further comprising implanting said ion species into at least one subsequently processed substrate using said implantation tool operated with said corrected tool setting.

4. The method of claim 2, wherein substantially amorphizing at least a portion of said semiconductor region comprises implanting a second ion species other than said specified ion species.

5. The method of claim 4, wherein an implantation energy for said second ion species is selected so as to obtain an average penetration depth for said second ion species that exceeds an average penetration depth of said specified ion species.

6. The method of claim 1, further comprising determining an amount of energy contamination for at least one second tool setting for said specified implantation energy to establish a relationship between at least one tool parameter and the amount of energy contamination.

7. The method of claim 6, wherein said at least one tool parameter is at least one of an extraction energy and a beam pipe vacuum.

8. The method of claim 1, wherein said substantially amorphous substrate is comprised of substantially the same material as said semiconductor region.

9. The method of claim 1, wherein determining an amount of energy contamination includes obtaining measurement data of a vertical implantation profile in said substantially amorphous substrate and estimating said amount of energy contamination on the basis of said measurement data.

10. The method of claim 9, further comprising comparing said measurement data with calculated data obtained from a simulation of said implantation of the specified species into said substantially amorphous substrate.

11. The method of claim 1, wherein said semiconductor region is an active region for forming drain and source areas of a field effect transistor.

12. The method of claim 11, wherein said specified implantation energy is in the range of approximately 500 eV to 10 keV.

13. The method of claim 12 and claim 4, wherein said second ion species is one of xenon, argon, germanium and silicon.

14. The method of claim 1, wherein said semiconductor region has a surface with a predefined crystalline orientation, the method further comprising tilting said semiconductor region with respect to an ion beam of said specified ion species so as to form an angle between said predefined crystalline orientation and said ion beam that is at least 5 degrees.

15. A method of adjusting a penetration depth of ions, the method comprising:
providing a substantially amorphized semiconductor layer on a substrate, said substantially amorphized semiconductor layer having a predefined depth;
determining penetration depths within said substantially amorphized semiconductor layer for a specified ion species for a specified implantation tool for a plurality of different tool settings for a predefined desired implantation energy;
based on said determined penetration depths, selecting a tool setting in conformity with a desired dopant distribution; and
implanting said ion species with said desired implantation energy into a second substrate having provided thereon said substantially amorphized semiconductor layer.

16. The method of claim 15, wherein providing said substantially amorphized semiconductor layer includes providing a crystalline semiconductor layer and implanting ions of a second species other than said specific ion species to substantially amorphize said semiconductor layer at least to said predefined depth.

17. The method of claim 15 or 16, wherein said second substrate is a product substrate for forming circuit elements with said specified implantation tool operated with said selected tool setting.

18. The method of claim 15, wherein said desired implantation energy is lower than an energy used to extract said specified ion species from an ion source of said specified implantation tool.

19. The method of claim 15, wherein determining said penetration depths includes varying at least an extraction energy and an acceleration energy of said specified ion species.

20. The method of claim 19, further comprising monitoring a beam pipe vacuum of said implantation tool and adjusting an acceleration energy on the basis of said beam pipe vacuum.

21. A method of adjusting an implantation tool used for creating a desired dopant profile in a semiconductor region, the method comprising:
implanting a specified ion species into a pre-amorphized portion of said semiconductor region at a desired implantation energy;
determining a dopant profile of said ion species in said pre-amorphized portion;
estimating a contribution of said dopant profile that is substantially created by non-charged particles; and
selecting a tool setting for said implantation tool for the desired implantation energy for said specified ion species on the basis of said estimated contribution.

22. The method of claim 21, further comprising implanting a second ion species into said semiconductor region so as to form said pre-amorphized portion.

23. The method of claim 22, wherein an implantation energy of said second species is selected so as to substantially amorphize said portion to a depth for which said specified ion species is confined substantially completely within said amorphized portion during implantation with said implantation energy.

24. The method of claim 21, further comprising processing at least one product substrate to form a plurality of circuit elements thereon by using said implantation tool operated with said selected tool setting.

25. The method of claim 22, wherein said second ion species is selected so as to obtain said substantially amorphized portion with an implantation dose in the range of approximately 5×10¹³ to 4×10¹⁴ ions per cm².

26. The method of claim 25, wherein said second ion species comprises at least one of germanium and silicon.

27. The method of claim 25, wherein said second ion species comprises at least one of xenon, argon and krypton.

28. The method of claim 21, wherein said desired implantation energy is lower than an extraction energy for creating said specified ion species.

29. An implantation tool, comprising:
an ion generation source configured to create ions of at least one specified species with a controllable average extraction energy;
a controllable acceleration section configured to apply a specified energy to said at least one species;
a mass and energy discriminator configured to select a mass and an implantation energy of particles entering said mass and energy discriminator;
a vacuum source connected to a beam pipe; and
a control unit operatively connected to at least said ion generation source and said controllable acceleration section, said control unit being configured to control a non-charged particle flow created during implantation of said at least one specified species on the basis of at least one depth profile of said specified species.
